(19) United States
(12) Patent Application Publication
(10) Pub. No.: US 2026/0124712 A1
(43) Pub. Date: May 7, 2026

(54) CHEMICAL MECHANICAL POLISHING PADS, METHODS OF MANUFACTURING CHEMICAL MECHANICAL POLISHING PADS, AND METHODS OF MANUFACTURING A SEMICONDUCTOR DEVICE

(71) Applicant: Taiwan Semiconductor Manufacturing Company, Ltd., Hsinchu (TW)

(72) Inventors: Jeng-Chi LIN, Hsinchu (TW); Chi-Hsiang SHEN, Hsinchu (TW); Te-Chien HOU, Hsinchu (TW); Chen-Hsueh LIN, Hsinchu (TW); Jui Yu PAI, Hsinchu (TW); Shang-Tzu LIU, Hsinchu (TW); Tang-Kuei CHANG, Hsinchu (TW); Hui-Chi HUANG, Hsinchu (TW); Kei-Wei CHEN, Hsinchu (TW)

(73) Assignee: Taiwan Semiconductor Manufacturing Company, Ltd., Hsinchu (TW)

(21) Appl. No.: 18/935,085

(22) Filed: Nov. 1, 2024

(51) Int. Cl. B24B 37/24; B24B 37/22; B24B 37/26; H01L 21/02

(52) U.S. Cl. CPC B24B 37/24; B24B 37/22; B24B 37/26; H10P 90/123

(57) ABSTRACT

A chemical mechanical polishing (CMP) pad includes a polishing surface including a first region including a hydrophobic character and a second region including a hydrophilic character. A method of manufacturing a CMP pad includes forming a polishing surface of the CMP pad to include a first region including a hydrophobic character and a second region including a hydrophilic character. A method of manufacturing a semiconductor device includes polishing a wafer by pressing a surface of the wafer against a polishing surface of a CMP pad while rotating both the wafer and the CMP pad, and supplying a slurry on the polishing surface of the CMP pad.

### BACKGROUND

Polishing such as chemical mechanical polishing (CMP) is utilized during the manufacturing of semiconductor devices. However, problems can arise when attempting to uniformly polish wafer substrates or semiconductor device structures formed thereon.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 schematically illustrates a CMP apparatus 1 according to an embodiment.

FIGS. 2, 3, and 4 schematically illustrate stages of a method of manufacturing a semiconductor device, according to an embodiment.

FIG. 5 schematically illustrates a stage of forming a top pad layer according to an embodiment.

FIG. 6 schematically illustrates an embodiment of a sub pad layer.

FIG. 7 schematically illustrates an embodiment of the top pad layer shown in FIG. 5 affixed over the sub pad layer shown in FIG. 6.

FIGS. 8A and 8B schematically illustrate cross-sectional elevation views taken along centers of grooves extending across CMP pads, according to embodiments.

FIGS. 9A and 9B schematically illustrate plan views of grooves formed in CMP pads according to embodiments.

FIG. 10 schematically illustrates water droplets disposed on a polishing surface of a polishing pad according to an embodiment.

FIG. 11 schematically illustrates the polishing pad of FIG. 10 under applied centrifugal force, according to an embodiment.

FIGS. 12A, 12B, 12C, 12D, 12E, and 12F schematically illustrate stages of a method manufacturing a CMP pad, according to an embodiment.

FIG. 13A schematically illustrates the interaction between a sulfobetaine methacrylate molecule and water molecules, according to an embodiment.

FIG. 13B schematically illustrates an embodiment after surface treating a pad with sulfobetaine methacrylate, according to an embodiment.

FIGS. 14A, 14B, 14C, and 14D schematically illustrate stages of a method manufacturing a CMP pad, according to an embodiment.

FIGS. 15A, 15B, 15C, 15D, and 15E schematically illustrate stages of a method manufacturing a CMP pad, according to an embodiment.

FIGS. 16A and 16B schematically illustrate views of an embodiment of a surface-treated polishing surface of a CMP pad, according to an embodiment.

FIG. 17 schematically illustrates a plan view of a CMP pad under operation, according to an embodiment.

FIG. 18 schematically illustrates a plan view of a CMP pad under operation, according to an embodiment.

FIGS. 19A, 19B, and 19C illustrate wafer polishing profiles according to embodiments.

FIG. 20 schematically illustrates a plan view of a CMP pad having a polishing head and wafer disposed thereon, according to an embodiment.

FIG. 21 schematically illustrates a plan view of a CMP pad having a polishing head and wafer disposed thereon, according to an embodiment.

FIG. 22 schematically illustrates a cross-section of a CMP pad according to an embodiment.

FIG. 23 schematically illustrates a cross-section of an enlarged region of the pad shown in FIG. 22, according to an embodiment.

FIG. 24 schematically illustrates the cross-section shown in FIG. 23 during a CMP process, according to an embodiment.

FIG. 25 shows a flow chart of a method of manufacturing a CMP pad according to some embodiments.

FIG. 26 shows a flow chart of method of manufacturing a semiconductor device, according to embodiments.

FIG. 27 schematically illustrates an embodiment of a CMP system according to an embodiment.

FIG. 28 is a block diagram illustrating a computing system 710 for controlling a CMP system, according to an embodiment.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

Chemical mechanical polishing (CMP), also referred to as chemical mechanical planarization, includes smoothing or abrading surfaces of a wafer. In some embodiments, CMP acts through a combination of chemical and mechanical forces by chemical reaction with material on the wafer and abrasive polishing of the material. In some embodiments, the CMP operation uses a slurry, also referred to as a polishing liquid, including abrasives and various other chemical constituents. A slurry can be applied to a polishing pad, also referred to herein as a CMP pad. A wafer can be pressed against the polishing pad by a polishing head. In some embodiments, the wafer is held on the polishing head by a retaining ring. In some embodiments, the polishing head rotates to remove material from the wafer and smooth any irregular topography.

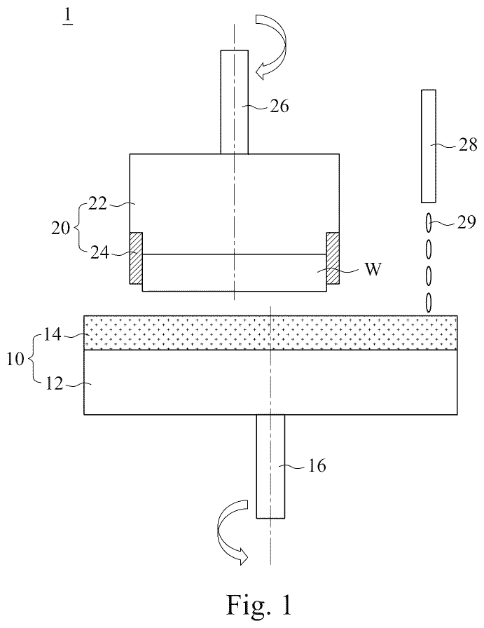

FIG. 1 schematically illustrates a CMP apparatus 1 according to an embodiment. As depicted in FIG. 1, the CMP apparatus 1 includes a polishing wheel assembly 10 and a polishing head 20. The polishing wheel assembly 10 includes a polishing platen 12 and a polishing pad 14. The polishing platen 12 is coupled to a spindle (or a shaft) 16. The spindle 16 can be rotated by any suitable motor or driving mechanism. The polishing pad 14 is attached to the polishing platen 12 and can be rotated along with the polishing platen 12. The polishing head 20 includes a wafer carrier 22 configured to hold or grip a wafer W. The wafer carrier 22 is coupled to another spindle (or a shaft) 26. The spindle 26 can be rotated by any suitable motor or driving mechanism. The rotation of the wafer carrier 22 and the rotation of the polishing platen 12 can be independently controlled. The rotational direction of the wafer carrier 22 and the rotational direction of the polishing platen 12 can be independently clockwise or counterclockwise. The wafer carrier 22 further includes a retainer ring 24 for retaining the wafer W to be polished. The retainer ring 24 can prevent the wafer W from sliding out from under the wafer carrier 22 as the wafer carrier 22 moves.

In some embodiments, during CMP operation the polishing pad 14 and the wafer W are both rotated at appropriate rates. The spindle 26 applies a load to the wafer carrier 22, which applies the load against the wafer W, which contacts the polishing pad 14. Thus, the wafer W or material formed thereon is polished. During the CMP operation, a slurry introduction device 28 introduces a slurry 29 on the polishing pad 14. In some embodiments, a computing system is used to control the operation of a CMP apparatus.

A slurry composition can be tailored for specific CMP operations depending on one or more of the composition and structure of the material to be polished. The slurry 29 can include one or more types of abrasive particles. Examples of useful abrasive particles include silicon oxide, colloidal silicon oxide, cerium oxide, cerium hydroxide, titanium oxide, and aluminum oxide. In some embodiments, abrasive particles have sizes ranging from about 10 nm to about 10 μm. The slurry 29 can include a liquid medium including one or more of deionized water, alcohol, or any other useful solvent. In some embodiments, the slurry 29 is aqueous. The slurry 29 can also include one or more additives to tailor polishing objectives such as polishing selectivity of one material over another material, chemical modification of a material to be polished, and desired material removal rate. According to some embodiments, additives include one or more of a surfactant, an oxidizer, a hydrolyzer, a pH adjuster, or a polymer. In some embodiments, a slurry has a pH within a range from about 2 to about 10. Prior to use, the slurry can be homogenized to ensure proper mixing and dispersion of components of the slurry. In some embodiments, the slurry 29 is stored in separate containers having different components, and the components are mixed at the time of use. In some embodiments, additives are introduced to the slurry at the time of use.

A wafer to be polished by CMP can be a blank wafer or a wafer having one or more layers or structures formed thereon. A wafer can have one or more semiconductor devices formed thereon. In some embodiments, the wafer is a semiconductor wafer including a semiconductor substrate (e.g., including silicon, a Group IV-IV semiconductor material, a Group III-V semiconductor material, or the like), active devices (e.g., transistors, or the like) on the semiconductor substrate, and/or various interconnect structures. Interconnect structures can include conductive features, which electrically connect active devices to form functional circuits. In some embodiments, semiconductor devices include a field effect transistor (FET) such as a fin FET, a gate-all-around FET, a nanowire FET, a sheet FET, a nanosheet FET, or nanotube FET.

A surface of a wafer to be polished can include a single type of material or two or more different materials exposed in a structure to be polished. Examples of materials that can be on a surface of a wafer to be polished include any one or more of silicon (e.g., polycrystalline, monocrystalline, doped, undoped), silicon oxide (e.g., SiO, SiO₂, SiOₓ), silicon nitride (e.g., SiN, Si₃N₄), silicon oxynitride, silicon oxycarbonitride, tungsten, cobalt, copper, molybdenum, ruthenium, tantalum, carbon, among other materials used in semiconductor devices.

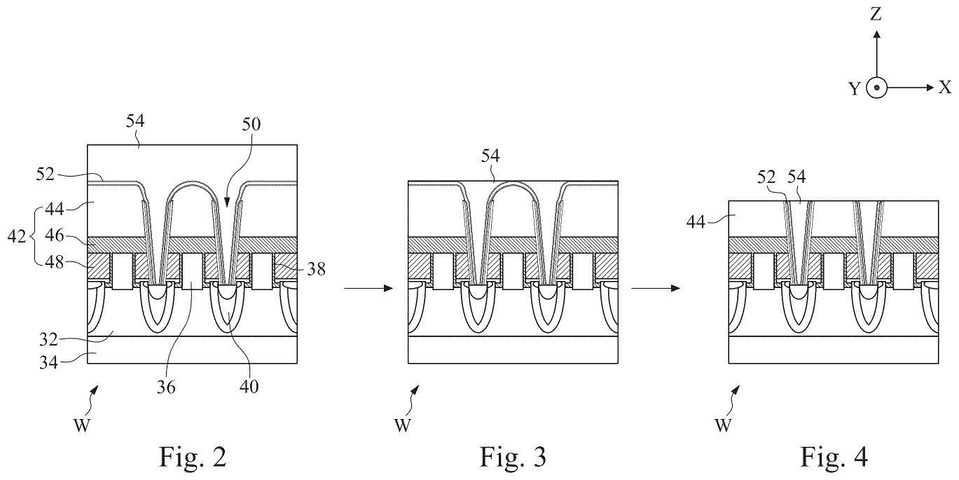

FIGS. 2, 3, and 4 schematically illustrate stages of a method of manufacturing a semiconductor device, according to an embodiment. FIG. 2 illustrates a wafer W including a fin structure 32 disposed over a semiconductor substrate 34. The fin structure 32 extends in a Y-direction across the substrate. A plurality of metal gates 36 are disposed over regions of the fin structure 32 and extend in the Y-direction. Gate sidewall spacers 38 cover the sides of the metal gates 36. Source/drain regions 40 are disposed in recesses formed in the fin structure 32 between the metal gates. In the illustrated embodiment, the source/drain regions include a multilayered structure. A multilayered insulating structure 42 including a first interlayer dielectric (ILD) layer 44, a second ILD layer 46, and a third ILD layer 48 is disposed over the fin structure 32. In some embodiments, the ILD layers are formed of silicon oxide, silicon nitride, or other suitable insulating material. Openings 50 extend through the multilayered insulating structure 42 and are lined with a multilayer liner 52. The openings 50 are filled with a metal material 54, e.g., tungsten. FIG. 3 illustrates a structure after performing CMP on the structure in FIG. 2 to perform bulk removal of the metal material 54. FIG. 4 illustrates a structure after performing CMP on the structure in FIG. 3 to finely polish the structure and expose portions of the first ILD layer 44, the multilayer liner 52, and the metal material 54.

A polishing pad used for CMP can include one or more layers. In some embodiments, a CMP pad exhibits acid and alkali resistance and is suitable for use in pH environments ranging from about 2 pH to about 10 pH. In some embodiments, the CMP pad has thermal resistance and can be used in temperatures above 80° C. In some embodiments, the CMP pad has good mechanical strength and durability and is non-flammable. In some embodiments, the CMP pad has a hard structure and is usable in a buck polishing procedure. In some embodiments, the CMP pad has a soft structure and is usable in a buff polishing procedure. In some embodiments, the polishing pad includes a top pad layer disposed over a sub pad layer.

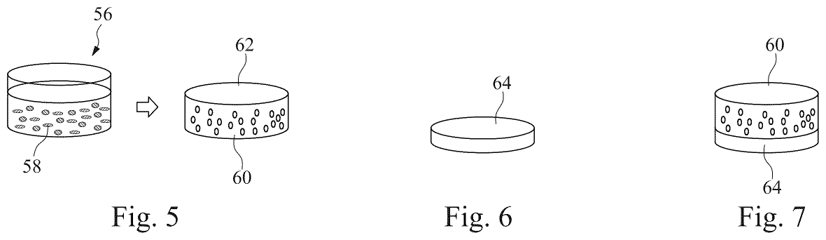

FIG. 5 schematically illustrates an embodiment of a stage of forming a top pad layer. Components 58 of the top pad layer are mixed in a tank 56. Polymerized components can then be drawn through a bath, e.g., water, to introduce the pores within the polymerized material to form the top pad layer 60. The porous top pad layer 60 can then be dried. The surface of the top pad layer can be buffed to open pores and form a polishing surface 62. FIG. 6 schematically illustrates an embodiment of a sub pad layer 64. In some embodiments, the sub pad layer is formed of a different material than the top pad layer using a separate process. FIG. 7 schematically illustrates an embodiment where the top pad layer 60 is affixed over the sub pad layer 64. The top pad layer can be affixed over the sub pad layer using an adhesive, in some embodiments. The stack of the top pad layer and sub pad layer can be pressed between heating plates, in some embodiments.

In some embodiments, one or more grooves are formed in the polishing surface of the polishing pad. In some embodiments, the grooves are formed by cutting, milling, machining, molding, grinding, or any other means of forming grooves in the top pad layer. In some embodiments, the grooves serve to remove and transport polishing byproducts as well as slurry from the polishing surface to a peripheral edge of the polishing pad. In some embodiments, the grooves prevent the formation of polishing marks by trapping the polishing particles within the grooves so that during polishing, the contact area of the polishing particles in the grooves forms a line of contact area across the polishing surface as opposed to point contact areas. Grooves can be formed in any arrangement on a top pad layer such as any one or more of radial, concentric circles, horizontal, vertical, lattice, grid, or star configurations. In some embodiments, the grooves include a varying groove depth from the center of the top pad layer to the edge.

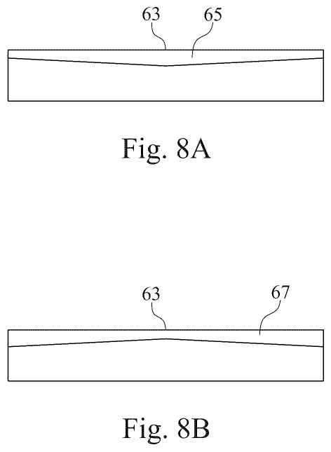

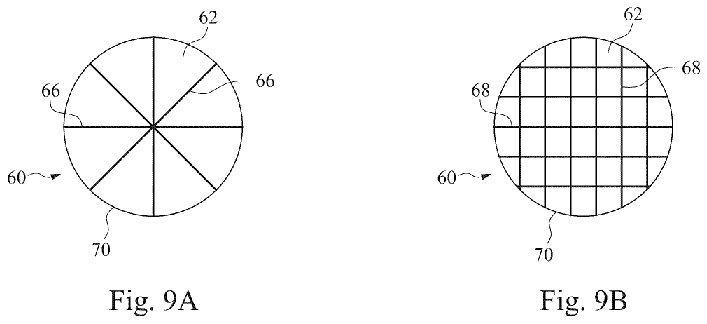

FIGS. 8A and 8B schematically illustrate elevational cross-sections taken along centers of grooves extending across CMP pads, according to some embodiments. A polishing surface 63 is visible in the background behind the grooves. In FIG. 8A, the groove 65 decreases in depth along with increased distance from the center of the CMP pad to the peripheral edge of the CMP pad. In FIG. 8B, the groove 67 increases in depth along with increased distance from the center of the CMP pad to the peripheral edge of the CMP pad. FIG. 9A schematically illustrates a plan view of an embodiment of a top pad layer 60 including grooves 66 that intersect on the polishing surface 62 and extend radially to a periphery 70 of the top pad layer. FIG. 9B schematically illustrates a plan view of an embodiment of a top pad layer 60 including grooves 68 arranged in a grid pattern on the polishing surface 62 of a top pad layer 60 and extend to the periphery 70 of the top pad layer.

In some embodiments, an aqueous slurry is used to conduct CMP of one or more materials disposed or formed on a wafer. Water present in an aqueous slurry can be used to hydrolyze one or more materials on the surface of a wafer to be polished. After being hydrolyzed, the materials may be more susceptible to removal by mechanical forces applied by abrasive particles in the slurry. In an embodiment, Si₃N₄ exposed on a surface being polished can be hydrolyzed according to the following formula:

Si₃N₄+6H₂O→3SiO₂+4NH₃.

A layer of SiO₂ formed through hydrolysis of Si₃N₄ can be removed through the mechanical action of the abrasive particles in the slurry.

In an embodiment, crystalline Si exposed on a surface being polished can be hydrolyzed in an alkaline aqueous slurry, according to the following formula:

Si+2OH⁻+2H₂O→Si(OH)₄+H₂

A layer of Si(OH)₄ formed through hydrolysis Si can be removed through the mechanical action of the abrasive particles in the slurry.

In some embodiments, a CMP pad includes a polishing surface including a hydrophobic character. In some embodiments, a CMP pad includes a polishing surface including a hydrophilic character. In some embodiments, a hydrophobic character corresponds to a material of a polishing surface exhibiting a contact angle of greater than or equal to 90°, and a hydrophilic character corresponds to a material of a polishing surface exhibiting a contact angle of less than 90°. In some embodiments, a contact angle of a clean sample of a polishing surface of a CMP pad can be measured using a goniometer such as an Ossila L2004A Contact Angle Goniometer. Instructions for the use of an Ossila L2004A are provided in the Contact Angle Goniometer User Manual, Manual Version 1.2.E, Ossila Limited, 2023, which are incorporated herein by reference in their entirety.

It has been discovered that a CMP pad including a polishing surface including one or more regions including a hydrophobic character and one or more regions including a hydrophilic character can be used to influence the action of slurries on the pad. In an embodiment, an aqueous slurry is used with a CMP pad including a polishing surface including one or more regions including hydrophobic character and one or more regions including hydrophilic character. The aqueous slurry tends to accumulate on the one or more regions including hydrophilic character and tends to be transported away from the one or more regions including hydrophobic character. The one or more hydrophilic regions can be disposed to contact a wafer to be polished, retain the slurry against the wafer, and assist with hydrolysis and removal of material on the wafer. In another embodiment, a slurry having a non-polar character will tend to accumulate on one or more hydrophobic regions and will tend to be transported away from one or more hydrophilic regions under centrifugal force.

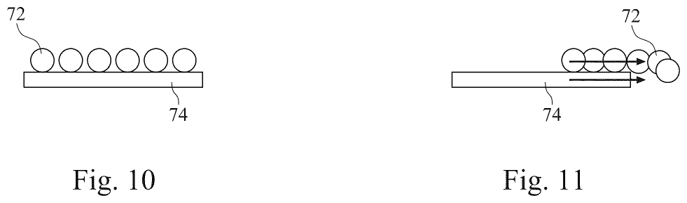

In some embodiments, a polishing surface or a portion of a polishing surface including a hydrophobic character facilitates the movement of an aqueous slurry across the polishing pad under centrifugal force applied by the platen. FIG. 10 schematically illustrates an embodiment of water droplets 72 disposed on a polishing surface of a polishing pad 74 that includes a hydrophobic character. The water droplets 72 stand on the polishing surface with a high contact angle. FIG. 11 schematically illustrates the polishing surface of FIG. 10 under an applied centrifugal force through rotation of the polishing pad. The water droplets 72 slip off the pad 74 under the centrifugal force.

It has also been discovered that a layout of regions including hydrophobic and/or hydrophilic character on a polishing surface can be configured to achieve specific polishing profiles on a wafer depending on the composition of the slurry. In some embodiments, a polishing surface includes one or more regions including a hydrophobic character and one or more regions including a hydrophilic character. The hydrophobic and hydrophilic regions can be formed in any shape such as circles, rectangles, triangles, squares, or irregular shapes, and can have any size smaller than the size of the CMP pad.

In some embodiments, a first region of the polishing surface includes a hydrophobic character, and a second region of the polishing surface includes a hydrophilic character. In some embodiments, the first region surrounds the second region. In some embodiments, the second region surrounds the first region. In some embodiments, the polishing surface further includes a third or more regions including a hydrophilic or a hydrophobic character. In some embodiments, the third region including the hydrophilic character surrounds the first region having the hydrophobic character when the first region surrounds the second region including the hydrophilic character. In some embodiments, the third region including the hydrophobic character surrounds the second region including the hydrophilic character when the second region surrounds the first region including the hydrophobic character.

In some embodiments, the polishing surface includes one or more regions including a hydrophobic character and one or more regions including a hydrophilic character such that the regions are arranged in concentric circles and the adjacent concentric circles respectively include a different character. For example, a hydrophobic region can be adjacent to a hydrophilic region, a hydrophobic region can be adjacent to a more hydrophobic region, or a hydrophilic region can be adjacent to a more hydrophilic region. In some embodiments, a region at the center of a polishing surface has a hydrophilic character, and each successive region from the center toward the peripheral edge of the polishing surface has a less hydrophilic character or a more hydrophobic character. In some embodiments, a region at the center of a polishing surface has a hydrophobic character, and each successive region toward the peripheral edge of the polishing surface has a less hydrophobic character or more hydrophilic character.

In some embodiments, a polishing surface exhibits a gradient of increasing hydrophilicity, increasing hydrophobicity, decreasing hydrophilicity, or decreasing hydrophobicity, with increased distance from the center of the polishing surface toward the peripheral edge of the polishing surface. In some embodiments, the hydrophobicity or the hydrophilicity of a polishing surface can be configured to fluctuate according to pattern, e.g., increase, decrease, increase, along with increased distance from the center of the polishing surface toward the peripheral edge.

In some embodiments, regions of a polishing surface are surface treated to include a hydrophilic or a hydrophobic character. In some embodiments, providing a gradient or gradually changing hydrophobicity or hydrophilicity of a polishing surface from the center to the edge of the polishing surface is achieved by applying a surface treatment agent at varying concentrations across the polishing surface.

In some embodiments, a top pad layer of a CMP pad can be formed of two or more different top pad layer sections, where the different top pad layer sections include different character, e.g. hydrophobic or hydrophobic character, and the different sections are exposed on a polishing surface of the top pad layer.

In some embodiments, a CMP pad, a top pad layer, or a section of a top pad layer including a hydrophobic character is made of one or more of polytetrafluoroethylene (PTFE), polypropylene (PP), polyoxymethylene (POM), polydimethylsiloxane (PDMS), polyethylene terephthalate (PET), polyethylene (PE), phenolic resin, silicone rubber, polyimide (PI), and epoxy resin. In some embodiments, a CMP pad, a top pad layer or a section of a top pad layer includes an aromatic polyimide having the following formula:

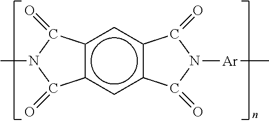

In some embodiments, a CMP pad, a top pad layer, or a section of a top pad layer including a hydrophilic character is made of one or more of polyvinyl alcohol (PVA), polyethylene glycol (PEG), polyacrylamide (PAM), poly(2-hydroxyethyl methacrylate) (PHEMA), polyvinylpyrrolidone (PVP), poly(2-acrylamido-2-methyl-1-propane sulfonic acid) (PAMPS), poly(vinyl alcohol-co-vinyl acetate), cellulose, cellulose derivative (e.g., hydroxyethyl cellulose), polyurethane (PU), polyamide (PA), polyacrylic acid (PAA), and polyamic acid.

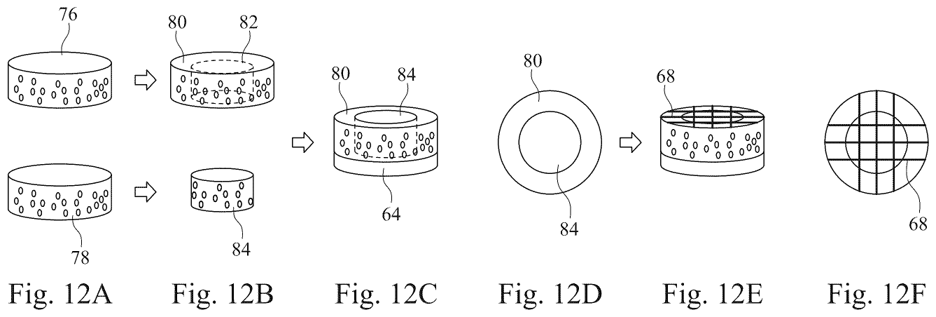

In some embodiments, a method of manufacturing a CMP pad includes forming regions of a polishing surface having different character with regard to hydrophobicity and hydrophilicity by forming separate sections of top pad layers of different materials having the desired hydrophobic and hydrophilic characters in shapes that will provide a desired pattern of the different regions of the polishing surface, and fitting the separate sections together to form a unitary top pad layer including the polishing surface. FIGS. 12A, 12B, 12C, 12D, 12E, and 12F schematically illustrate stages of a method manufacturing a CMP pad including a region including a hydrophobic character and a region including a hydrophilic character, according to an embodiment. FIG. 12A illustrates a top pad layer 76 including a hydrophobic character and a top pad layer 78 including a hydrophilic character. FIG. 12B illustrates a hydrophobic section 80 of a top pad layer including an opening 82 formed by cutting the opening in the top pad layer 76 shown in FIG. 12A. FIG. 12B also illustrates a hydrophilic section 84 of a top pad layer formed by cutting the top pad layer 78 shown in FIG. 12A. The hydrophilic section 84 is cut to fit within the opening 82 of the hydrophobic section 80. The cutting can be conducted by any useful method such as laser cutting or cutting with a blade. The cutting can be robotically controlled by a computing system based on a desired layout of the hydrophobic and hydrophilic regions on the polishing surface. Alternatively, the cutting can be conducted by hand. FIG. 12C shows a perspective view of a polishing pad assembled by fitting the hydrophilic section 84 in the opening 82 of the hydrophobic section 80 and affixing both the hydrophobic section 80 and the hydrophilic section 84 to a sub pad layer 64 using an adhesive or other suitable means of fixation. In some embodiments, the outer periphery of the hydrophilic section 84 is fixed to an inner periphery of the opening 82 using an adhesive or other suitable means of fixation. FIG. 12D shows a plan view of the polishing surface of the polishing pad shown in FIG. 12C. FIG. 12E illustrates the pad shown in FIG. 12C after forming grooves 68 in the polishing surface of the pad. FIG. 12F shows a plan view of the polishing pad shown in FIG. 12E. Additional sections of top pad layers including hydrophobic or hydrophilic characters can be cut and combined with the structures shown in FIGS. 12C, 12D, 12E, and 12F.

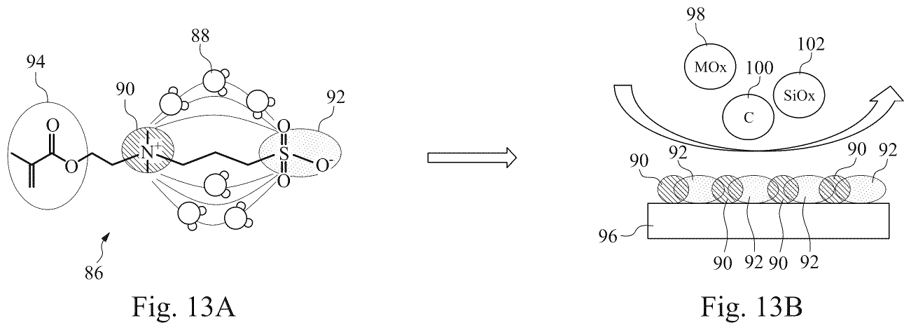

In some embodiments, a method of manufacturing a CMP pad includes forming a polishing surface having regions with different characters with regard to hydrophobicity and hydrophilicity by providing a pad having either a hydrophobic or a hydrophilic character and surface treating one or more regions of a polishing surface of the top pad layer to have the other of a hydrophobic or a hydrophilic character. Any suitable surface treatment agent capable of imparting hydrophilic character to a hydrophobic top pad layer or imparting hydrophobic character to a hydrophilic top pad layer can be used. In some embodiments, a reactive zwitterionic surface treatment agent is used to form one or more regions including a hydrophilic character on a pad material including a hydrophobic character. In some embodiments, a surface treating agent is provided in a solution, e.g., an aqueous or solvent-based solution, and the solution is printed on a polishing surface in the desired layout. In some embodiments, the printing is conducted robotically and controlled with a computing system. In some embodiments, a zwitterionic additive contains both a cation group and an anion group and is used to provide a hydrophobic pad with a hydrophilic surface treatment. In an embodiment, sulfobetaine methacrylate (SBMA) is used to surface treat a polishing pad. FIG. 13A schematically illustrates the interaction between an SMBA molecule 86 and water molecules 88. The SMBA molecule includes a cationic ammonium moiety 90, an anionic sulfite moiety 92, and a methacrylate moiety 94. The ammonium and sulfite moieties form a dipole environment such that the ammonium moiety attracts oxygen atoms of water molecules and the sulfite moiety attracts hydrogen atoms of water molecules. FIG. 13B schematically illustrates an embodiment after surface treating a pad 96 with SMBA. In an embodiment, the SMBA is coated on the pad and the coated pad is exposed to ultraviolet (UV) light. The UV light causes the methacrylate moieties to react, attach or otherwise graft to the surface of the pad 96. The ammonium moieties 90 and sulfite moieties 92 provide a dipole hydrophilic layer on the polishing surface of the pad. The hydrophilic regions can repel materials such as metal oxides 98, materials containing carbon 100, and silicon oxide 102. In some embodiments, one or more regions of the pad are treated with SMBA have a hydrophilic character while one or more untreated regions of the pad maintain a hydrophobic character.

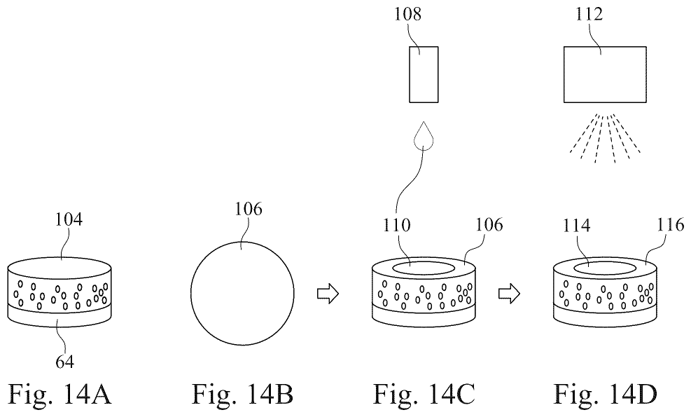

In some embodiments, a method of manufacturing a CMP pad includes forming a polishing surface including a first region including a hydrophobic character and a second region including a hydrophilic character. In some embodiments, the first region surrounds the second region. In other embodiments, the second region surrounds the first region. In some embodiments, the method includes forming the polishing surface through a process including providing a hydrophobic polymeric pad, surface treating a part of the hydrophobic polymeric pad with a surface treatment agent to form the second region, such that one or more portions of the hydrophobic polymeric pad that remain untreated form the first region of the polishing surface including the hydrophobic character. FIGS. 14A, 14B, 14C, and 14D schematically illustrate stages of a method manufacturing a CMP pad including a first region and a second region according to an embodiment. FIG. 14A illustrates a top pad layer 104 including a hydrophobic character affixed over a sub pad layer 64. FIG. 14B illustrates a plan view of the polishing surface 106 of the top pad layer in FIG. 14A. FIG. 14C illustrates a dispenser 108 applying a surface treatment agent 110 to a confined region of the polishing surface 106. FIG. 14D illustrates an ultraviolet exposure device 112 directing ultraviolet radiation to the polishing surface to create a region including a hydrophilic character 114 where the confined area of the surface treatment agent reacts with the polishing surface. In region 116, where the surface treatment agent is not applied, the polishing surface maintains a hydrophobic character. In some embodiments, one or more additional regions are treated with the surface treatment agent and exposed to ultraviolet light to form one or more additional regions including a hydrophilic character. In alternative embodiments, the untreated polishing surface has a hydrophilic character, and the surface treatment agent forms a hydrophobic region on the polishing surface when processed. In some embodiments, a dispenser is a printing device controlled by a computing system to print a desired pattern of the surface treatment agent on the polishing surface.

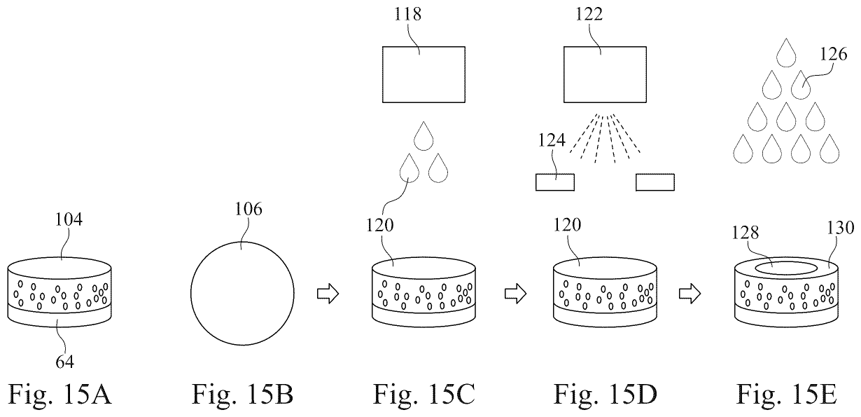

FIGS. 15A, 15B, 15C, 15D, and 15E schematically illustrate stages of a method manufacturing a CMP pad including a first region and a second region, according to an embodiment. FIG. 15A illustrates a top pad layer 104 including a hydrophobic character affixed over a sub pad layer 64. FIG. 15B illustrates a plan view of the polishing surface 106 of the top pad layer in FIG. 15A. FIG. 15C illustrates a dispenser 118 applying a surface treatment agent 120 to cover the entire polishing surface. FIG. 15D illustrates an ultraviolet exposure device 112 directing ultraviolet radiation through a mask 124 to the polishing surface to create a region including a hydrophilic character where the surface treatment agent reacts with the polishing surface. FIG. 15E illustrates rinsing 126 of the polishing surface with a solvent, e.g., water, to remove unreacted surface treatment agent while retaining the region 128 including a hydrophilic character. Regions 130 where the surface treatment agent is unreacted and rinsed away retain a hydrophobic character. In alternative embodiments, the untreated polishing surface has a hydrophilic character and the surface treatment agent forms a hydrophobic region on the polishing surface when processed with patterned radiation. In some embodiments, laser radiation is used to react a surface treatment agent with the polishing surface.

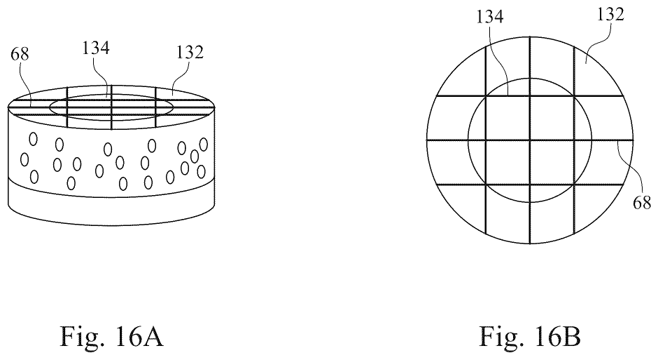

FIGS. 16A and 16B schematically illustrate perspective and plan views, respectively, of an embodiment of a surface-treated polishing surface including a region 132 including a hydrophobic character and a region 134 including a hydrophilic character after forming grooves 68 in the polishing surface.

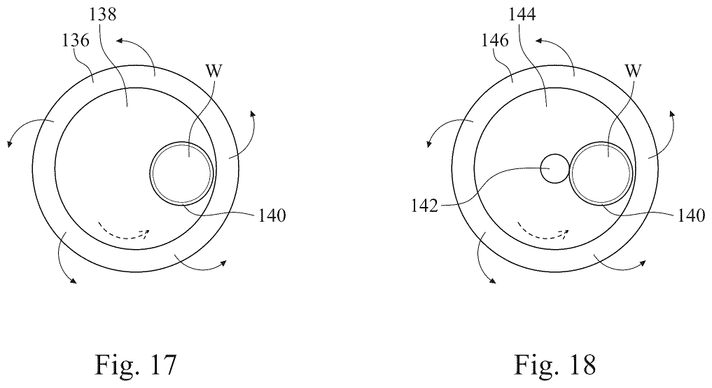

FIG. 17 schematically illustrates a plan view of an embodiment of a CMP pad under operation. Region 136 of the polishing surface includes a hydrophobic character and region 138 includes a hydrophilic character. In some embodiments, regions 136 and 138 are formed by assembling sections of a top pad layer having either hydrophilic or hydrophobic character. In some embodiments, regions 136 and 138 are formed by surface-treating the polishing surface. A polishing head 140 of a CMP apparatus positions a wafer W on region 138 including a hydrophilic character. In an embodiment, an aqueous slurry is supplied to region 138. The hydrophilic character of region 138 aids retention of the slurry on the wafer. When the aqueous slurry reaches region 136 under centrifugal force, the hydrophobic character of region 136 aids the expulsion of the slurry from the polishing surface.

In some embodiments, a polishing head has a diameter of about 350 mm, or a diameter ranging from about 250 mm to about 500 mm. In some embodiments, a polishing pad has a diameter of about 800 mm, or a diameter ranging from about 600 mm to about 1000 mm. In some embodiments, a region of a polishing surface including a hydrophilic character has a diameter ranging from about 300 mm to about 600 mm, or from about 400 mm to about 500 mm. In some embodiments, a slurry is deposited on a polishing surface in a location about 40 mm offset from the center of the polishing surface.

FIG. 18 schematically illustrates a plan view of an embodiment of a CMP pad under operation. Inner region 142 of the polishing surface includes a hydrophobic character, region 144 includes a hydrophilic character, and outer region 146 includes a hydrophobic character. In some embodiments, regions 142, 144, and 146 are formed by assembling sections of a top pad layer having either hydrophilic or hydrophobic character. In some embodiments, regions 142, 144, and 146 are formed by surface treating the polishing surface. A polishing head 140 of a CMP apparatus positions a wafer W on the region 144 including the hydrophilic character. In an embodiment, an aqueous slurry is supplied to the polish pad. Region 142 including the hydrophobic character attenuates the accumulation of the aqueous slurry in a central portion of the pad. The hydrophilic character of region 144 aids retention of the slurry on the wafer. As the slurry moves across the pad under centrifugal force, the region 146 including the hydrophobic character aids the expulsion of the slurry from the polishing surface.

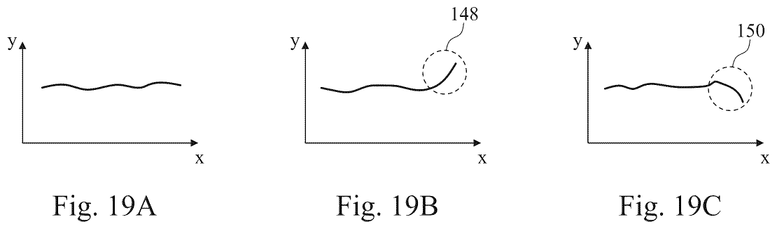

FIGS. 19A, 19B, and 19C illustrate wafer polishing profiles according to embodiments. The y-axes in FIGS. 19A, 19B, and 19C represent wafer thickness and the x-axes represent distance from a wafer center, with the wafer center being at the intersection between the x and y axes. FIG. 19A illustrates an embodiment where the wafer thickness is substantially uniform when measured at locations spanning from the wafer center to the wafer edge. FIG. 19B illustrates an embodiment where the wafer thickness is substantially uniform except in an edge region 148 having increased thickness. FIG. 19C illustrates an embodiment where the wafer thickness is substantially uniform except in an edge region 150 having decreased thickness. It is thought that wafer thickness in an edge region of a wafer is difficult to control due to the influence of a retainer ring of a polishing head on the CMP process.

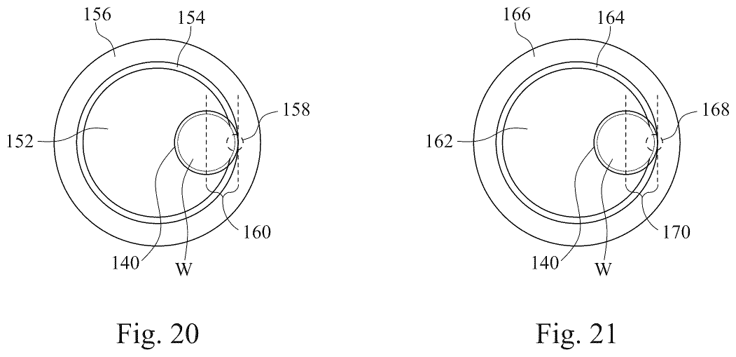

FIG. 20 schematically illustrates a plan view of an embodiment of a CMP pad and a polishing head 140 of a CMP apparatus positioning a wafer W on the pad. Inner region 152 of the polishing surface includes a hydrophilic character, a region 154 includes a hydrophobic character, and outer region 156 includes a hydrophilic character. In some embodiments, regions 152, 154, and 156 are formed by assembling sections of a top pad layer having either a hydrophilic or a hydrophobic character. In some embodiments, regions 152, 154, and 156 are formed by surface treating the polishing surface. The polishing head 140 positions the wafer W such that an edge of the wafer contacts the region 154 including a hydrophobic character within area 158 under the head. Annotated region 160 shows the wafer area spanning from the wafer center to the wafer edge. Region 160 corresponds to the areas of measurement of the wafer thickness profile shown in FIGS. 19A, 19B, and 19C. The hydrophobic character of region 154 can attenuate the presence of an aqueous slurry in area 158 and thereby reduce the polishing rate of material at the edge of the wafer in some embodiments. Thus, the CMP pad in FIG. 20 can be used to avoid the wafer profile shown in FIG. 19C having decreased thickness at a wafer edge due to aggressive or over polishing of the wafer edge.

FIG. 21 schematically illustrates a plan view of an embodiment of a CMP pad and a polishing head 140 of a CMP apparatus positioning a wafer W on the pad. The inner region 162 of the polishing surface includes a hydrophobic character, region 164 includes a hydrophilic character, and the outer region 166 includes a hydrophobic character. In some embodiments, regions 162, 164, and 166 are formed by assembling sections of a top pad layer including either a hydrophilic or a hydrophobic character. In some embodiments, regions 162, 164, and 166 are formed by surface treating the polishing surface. The polishing head 140 positions the wafer W such that an edge of the wafer contacts region 164 including a hydrophilic character within area 168 under the head. The annotated region 170 shows the wafer area spanning from the wafer center to the wafer edge. The annotated region 170 corresponds to the areas of measurement of wafer thickness profile shown in FIGS. 19A, 19B, and 19C. The hydrophilic character of region 164 can serve to promote the presence of an aqueous slurry in area 168 and thereby increase the polishing rate of material at the edge of the wafer, in some embodiments. Thus, the CMP pad in FIG. 21 can be used to avoid the wafer profile shown in FIG. 19B having increased thickness at a wafer edge due to insufficient polishing of the wafer edge.

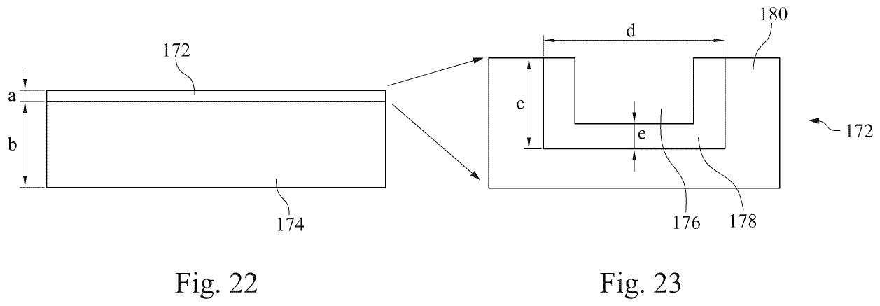

FIG. 22 schematically illustrates a cross-section of a CMP pad according to an embodiment. A modified area 172 has thickness (a) ranging from about 1 mm to about 10 mm, from about 3 mm to about 8 mm, or from about 4 mm to about 6 mm, according to some embodiments. A pad layer 174 has a thickness (b) ranging from about 5 mm to about 30 mm, from about 10 mm to about 25 mm, or from about 15 mm to about 20 mm, according to some embodiments. FIG. 23 schematically illustrates a cross-section of an enlarged region of the modified area 172 shown in FIG. 22, according to an embodiment. A groove 176 is formed in the modified area 172 and is surrounded by a region 178 including a hydrophobic character. In some embodiments, a pad has a plurality of grooves having the structure of groove 176 shown in FIG. 23 and any structure shown in FIGS. 8A, 8B, 9A, and 9B.

The region 178 including a hydrophobic character is surrounded by a region 180 including a hydrophilic character. The region 178 has a height (c) ranging from about 0.1 mm to about 5 mm, from about 1 mm to about 4 mm, or from about 2 mm to about 3 mm, according to some embodiments. A width (d) of the region spanning the groove 176 ranges from about 0.1 mm to about 7 mm, from about 1 mm to about 6 mm, or from about 2 mm to about 5 mm, according to some embodiments. A thickness (e) of the region 178 under the groove 176 ranges from about 0.1 mm to about 3 mm, from about 0.5 mm to about 2.5 mm, or from about 1.5 mm to about 2 mm, according to some embodiments.

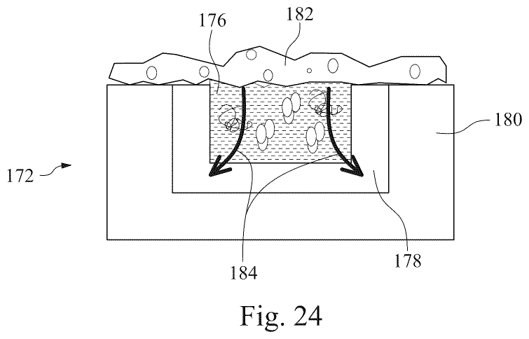

FIG. 24 schematically illustrates the cross-section of the enlarged region of the modified area 172 shown in FIG. 23 with an aqueous slurry 182 disposed across the polishing surface of the modified area 172, according to an embodiment. As a wafer is polished using the slurry, the slurry and material removed from the wafer fall into the groove under gravity. When the CMP pad including the modified area 172 is rotated, centrifugal force moves the slurry and material in the groove 176 toward the periphery of the pad, as schematically illustrated by arrows 184. The hydrophobic character of region 178 aids the movement of aqueous material in the groove 176 toward the periphery of the pad. The region 180 including a hydrophilic character facilitates retention of the slurry 182 against the wafer for polishing.

In some embodiments, slots for grooves are formed in a hydrophilic polishing surface, and liner materials, e.g., pad material including hydrophobic character and having U-shaped cross-sections are embedded in the slots to form regions 178 and grooves 176. In other embodiments, once grooves are formed in a hydrophobic polishing surface, regions of the polishing surface outside the grooves are surface treated to include a hydrophilic character while retaining the hydrophobic character inside the grooves. In other embodiments, once grooves are formed in a hydrophilic polishing surface, regions lining the grooves are surface treated so to have a hydrophobic character while the regions outside the grooves retain the hydrophilic character.

In some embodiments, a surface treatment agent is applied to a hydrophobic polishing surface in regions only outside the grooves, and the surface treatment agent is exposed to ultraviolet radiation to form regions outside the grooves including a hydrophilic character while retaining regions inside the grooves including a hydrophobic character. In some embodiments, the surface treatment agent is applied to the entire hydrophobic polishing surface, and patterned ultraviolet radiation is directed to only areas of the polishing surface outside the grooves to form regions including a hydrophilic character.

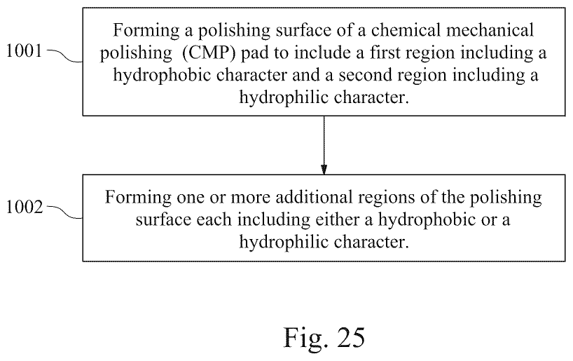

FIG. 25 shows a flow chart of a method of manufacturing a CMP pad according to some embodiments. The method includes an operation 1001 of forming a polishing surface of the CMP pad to include a first region including a hydrophobic character and a second region including a hydrophilic character. In some embodiments, the operation 1001 of forming the polishing surface includes forming a first section of pad including the hydrophobic character, forming a second section of pad including the hydrophilic character, combining the first and second sections to form a top pad layer including the polishing surface, and affixing the top pad layer over a sub pad layer. In some embodiments, the method optionally includes an operation 1002 of forming one or more additional regions of the polishing surface each including either a hydrophobic or a hydrophilic character. In some embodiments, the operation 1002 includes forming a third section of pad including a hydrophobic or hydrophilic character, and combining the third section of pad with the first and second sections of pad. In some embodiments, the operation 1001 of forming the polishing surface includes providing a hydrophobic polymeric pad, surface treating a part of the hydrophobic polymeric pad with a surface treatment agent to form the second region of the polishing surface including the hydrophilic character, wherein a portion of the hydrophobic polymeric pad not treated with the surface treatment agent forms the first region of the polishing surface including the hydrophobic character. In some embodiments, the operation 1002 of forming one or more additional regions of the polishing surface each including either a hydrophobic or a hydrophilic character includes surface treating one or more additional regions of the polishing surface to have the hydrophobic character.

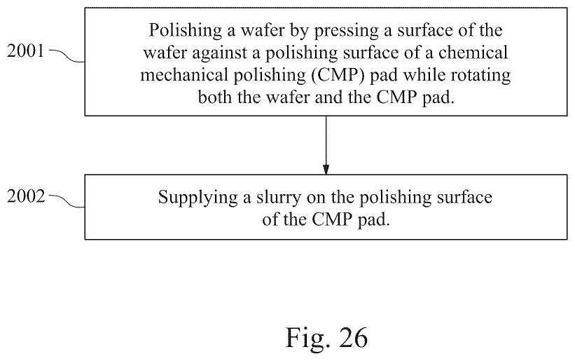

FIG. 26 shows a flow chart of a method of manufacturing a semiconductor device, according to embodiments. The method includes an operation 2001 of polishing a wafer by pressing a surface of the wafer against a polishing surface of a CMP pad while rotating both the wafer and the CMP pad. The method further includes an operation 2002 of supplying a slurry on the polishing surface of the CMP pad. The operation 2002 can be performed before or during operation 2001, in some embodiments.

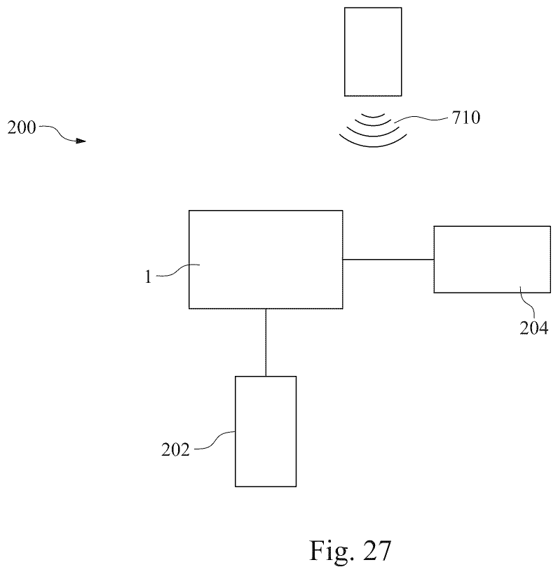

FIG. 27 schematically illustrates an embodiment of a CMP system 200 that includes a CMP apparatus 1, a wafer-handling system 202, a CMP pad forming tool 204, and a computing system 710. The CMP apparatus 1 is configured to perform one or more CMP operations. The wafer-handling system 202 is configured to move one or more wafers in and out of the CMP apparatus 1. The CMP pad forming tool 204 is configured to perform one or more methods of manufacturing a CMP pad provided herein.

The computing system 710 can be programmed to operate any one or more components of the CMP system 200 to perform any method provided in the present disclosure. In an embodiment, the computing system 710 is programmed to conduct operations including controlling the CMP apparatus 1, controlling the CMP pad forming tool 204, controlling the wafer-handling system 202. FIG. 27 illustrates the computing system 710 as being wirelessly connected to other components of the CMP system 200. However, the computing system 710 can be hardwired to one or more of the components of the CMP system 200.

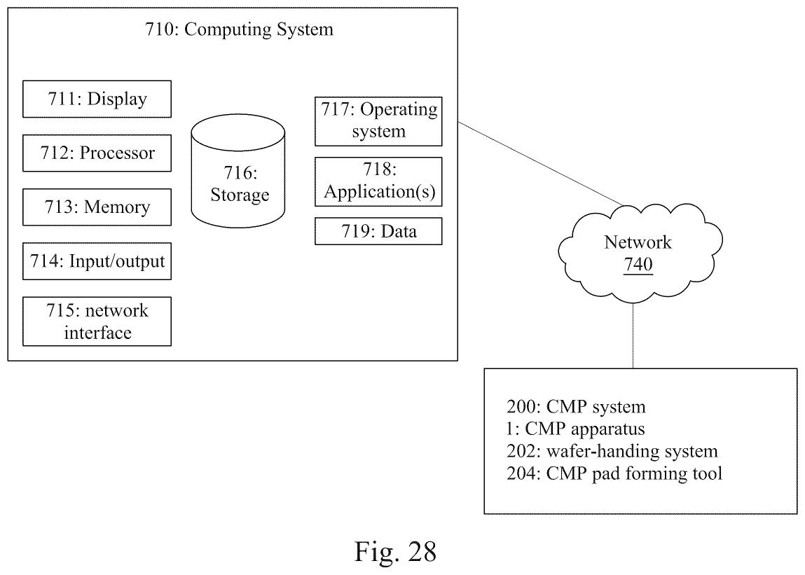

FIG. 28 is a block diagram illustrating an embodiment of a computing system 710 for controlling the operation of CMP system 200. In some embodiments, the computing system 710 is implemented using hardware or a combination of software and hardware, either in a dedicated server, integrated into another entity, or distributed across multiple entities such as via a cloud or wired network. The computing system 710 is communicably connected to the CMP system 200 using a wireless or wired network 740 to permit data exchange therebetween. The computing system 710 includes a display 711, a processor 712, a memory 713, an input/output interface 714, a network interface 715, and a storage 716 storing an operating system 717, programs or applications 718 such as applications for controlling CMP system 200. The processor 712 can be a general-purpose microprocessor, a microcontroller, or the like. The storage 716 can be a random access memory (RAM), a flash memory, a read-only memory (ROM), a hard or optical disk, cloud storage, or any other suitable storage device, for storing information and instructions to be executed by the processor 712. The processor 712 and storage 716 can be supplemented by, or incorporated in, special purpose logic circuitry.

The network interface 715 can include networking interface cards, such as Ethernet cards and modems. In some embodiments, the input/output interface 714 is configured to connect to a plurality of devices, such as an input device and/or an output device. Example input devices include a keyboard and a pointing device, e.g., a mouse or a trackball, by which a user can provide input to the computing system 710. Example output devices include display devices, such as LED (light emitting diode) or LCD (liquid crystal display) screens for displaying information to the user.

The applications 718 can include instructions which, when executed by the computing system 710 (or a processor 712 thereof), causes the computing system 710 (or the processor 712 thereof) to control the CMP system 200, and perform other operations, methods, and/or processes that are explicitly or implicitly described in the present disclosure.

The data 719 can include data including parameters used in the control operations, data that is received, for example, through the input/output interface 714 or through the network interface 715 transmitted from the CMP apparatus 1, the wafer-handling system 202, and/or the CMP pad forming tool 204, data for displaying on the display 711, data that is transmitted to or from the CMP apparatus 1, the wafer-handling system 202, and/or the CMP pad forming tool 204 via the network 740, or data generated during operation of the computing system 710.

A CMP pad including a polishing surface including plural regions of different character with respect to the hydrophobicity and hydrophilicity can be used to provide tailored performance of a slurry on the pad. In some embodiments, a hydrophilic region of a polishing surface aids the retention of an aqueous slurry on a wafer surface during processing. In some embodiments, a hydrophobic region of a polishing surface aids movement of an aqueous slurry to other regions or off the pad. In some embodiments, the methods, CMP pads, and CMP apparatuses according to the disclosure improve the efficiency of CMP operations in semiconductor manufacturing methods.

According to an embodiment, a chemical mechanical polishing (CMP) pad includes a polishing surface including a first region including a hydrophobic character and a second region including a hydrophilic character. In an embodiment, the first region surrounds the second region. In an embodiment, the polishing surface further includes a third region including a hydrophilic character. In an embodiment, the third region surrounds the first region. In an embodiment, the second region surrounds the first region. In an embodiment, the polishing surface further includes a third region including a hydrophobic character. In an embodiment, the third region surrounds the second region. In an embodiment, the polishing surface includes a hydrophobic polymeric material, and the second region of the polishing surface includes a surface treated area including the hydrophilic character. In an embodiment, the CMP pad further includes a top pad layer forming the polishing surface, wherein the top pad layer includes a first section including a hydrophobic polymeric material forming the first region and a second section including a hydrophilic polymeric material forming the second region. In an embodiment, the CMP pad further includes a plurality of grooves formed in the polishing surface. In an embodiment, the first region lines the grooves, and the second region is disposed outside the grooves.

According to another embodiment, a chemical mechanical polishing (CMP) pad includes a sub pad layer; and a top pad layer affixed over the sub pad layer, wherein the top pad layer includes a first section including a hydrophobic polymeric material and a second section including a hydrophilic polymeric material, and the first and second sections are exposed on a polishing surface of the top pad layer. In an embodiment, the first section surrounds the second section on the polishing surface. In an embodiment, the top pad layer further includes a third section including a hydrophilic polymeric material exposed on the polishing surface. In an embodiment, the third section surrounds the first section on the polishing surface. In an embodiment, the second section surrounds the first section on the polishing surface. In an embodiment, the top pad layer further includes a third section including a hydrophobic polymeric material exposed on the polishing surface. In an embodiment, the third section surrounds the second section on the polishing surface.

According to another embodiment, a chemical mechanical polishing (CMP) pad includes a polishing surface including one of the following structures (a), (b), (c), or (d): (a) a first region including a hydrophobic character and a second region including a hydrophilic character, wherein the first region surrounds the second region on the polishing surface, (b) a first region including a hydrophobic character, a second region including a hydrophilic character, and a third region including a hydrophilic character, wherein the first region surrounds the second region on the polishing surface, and the third region surrounds the first region on the polishing surface, (c) a first region including a hydrophobic character, a second region including a hydrophilic character, and a third region including a hydrophobic character, wherein the second region surrounds the first region on the polishing surface, and the third region surrounds the second region on the polishing surface, or (d) a plurality of grooves formed on the polishing surface, a first region including a hydrophobic character lining the grooves and exposed on the polishing surface, and a second region including a hydrophilic character on the polishing surface outside the grooves. In an embodiment, the polishing surface includes structure (d) and the first region extends outside the grooves to portions of the polishing surface proximal the grooves, and the first region is bounded by the second region.

According to another embodiment, a method of manufacturing a chemical mechanical polishing (CMP) pad includes forming a polishing surface of the CMP pad to include a first region including a hydrophobic character and a second region including a hydrophilic character. In an embodiment, the forming the polishing surface includes forming a first section of the CMP pad including the hydrophobic character, forming a second section of the CMP pad including the hydrophilic character, combining the first and second sections to form a top pad layer including the polishing surface, and affixing the top pad layer over a sub pad layer. In an embodiment, the first section of the pad surrounds the second section of pad on the polishing surface. In an embodiment, the forming the polishing surface further includes forming a third section of the pad including a hydrophilic character and combining the third section with the first and second sections of the pad. In an embodiment, the third section of the pad surrounds the first section of the pad on the polishing surface. In an embodiment, the second section of the pad surrounds the first section of the pad on the polishing surface. In an embodiment, the forming the polishing surface further includes forming a third section of the pad including a hydrophobic character, and combining the third section of the pad with the first and second sections of the pad so that the third section surrounds the second section of the pad on the polishing surface. In an embodiment, the third section of the pad surrounds the second section of the pad on the polishing surface. In an embodiment, the forming the polishing surface includes providing a hydrophobic polymeric pad, surface treating a part of the hydrophobic polymeric pad with a surface treatment agent to form the second region of the polishing surface including the hydrophilic character, wherein a portion of the hydrophobic polymeric pad not treated with the surface treatment agent forms the first region of the polishing surface including the hydrophobic character.

According to another embodiment, a method of manufacturing a chemical mechanical polishing (CMP) pad includes disposing a top pad layer over a sub pad layer, wherein the top pad layer includes a first section including a hydrophobic character and a second section including a hydrophilic character, and the first and second sections are exposed on a polishing surface of the top pad layer. In an embodiment, the method further includes forming the first and second sections of the top pad layer such that the first section surrounds the second section on the polishing surface. In an embodiment, the method further includes forming a third section of the top pad layer including a hydrophilic character such that the third section is exposed on the polishing surface and surrounds the first section on the polishing surface. In an embodiment, the method further includes forming the first and second sections of the top pad layer such that the second section surrounds the first section on the polishing surface. In an embodiment, the method further includes forming a third section of the top pad layer including a hydrophobic character such that the third section is exposed on the polishing surface and surrounds the second section on the polishing surface.

According to another embodiment, a method of manufacturing a chemical mechanical polishing (CMP) pad includes forming a polishing surface to include one of the following structures (a), (b), (c), or (d): (a) a first region including a hydrophobic character, a second region including a hydrophilic character, wherein the first region surrounds the second region on the polishing surface, (b) a first region including a hydrophobic character, a second region including a hydrophilic character, and a third region including a hydrophilic character, wherein the first region surrounds the second region on the polishing surface, and the third region surrounds the first region on the polishing surface, (c) a first region including a hydrophobic character, a second region including a hydrophilic character, and a third region including a hydrophobic character, wherein the second region surrounds the first region on the polishing surface, and the third region surrounds the second region on the polishing surface, or (d) a plurality of grooves formed in the polishing surface and lined with a material including a hydrophobic character exposed on the polishing surface, and a region of the polishing surface outside the grooves including a hydrophilic character. In an embodiment, the method includes the forming the polishing surface including the structure (a) through a process including providing a hydrophobic polymeric pad, surface treating a part of the hydrophobic polymeric pad with a surface treatment agent to form the second region of the polishing surface including the hydrophilic character, wherein a portion of the hydrophobic polymeric pad that is not treated with the surface treatment agent forms the first region of the polishing surface including the hydrophobic character. In an embodiment, the method includes the forming the polishing surface including the structure (b) through a process including providing a hydrophobic polymeric pad, surface treating the hydrophobic polymeric pad with a surface treatment agent to form the second and third regions of the polishing surface including the hydrophilic character, wherein a portion of the hydrophobic polymeric pad that is not treated with the surface treatment agent forms the first region of the polishing surface including the hydrophobic character. In an embodiment, the surface treating the parts of the hydrophobic polymeric pad with the surface treatment agent includes coating a surface of the hydrophobic polymeric pad with the surface treatment agent, and thereafter exposing the parts of the surface of the hydrophobic polymeric pad to a pattern of ultraviolet radiation to react the surface treatment agent with the hydrophobic polymeric pad and form the second and third regions of the polishing surface including the hydrophobic character, wherein a part of the hydrophobic polymeric pad that is not exposed to the pattern ultraviolet light forms the first region of the polishing surface including the hydrophobic character. In an embodiment, the method includes the forming the polishing surface including the structure (d) through a process forming the grooves in a surface of a hydrophobic polymeric pad forming the polishing surface, surface treating the region of the polishing surface outside the grooves with a surface treatment agent. In an embodiment, the method further includes exposing the polishing surface to ultraviolet radiation to react the surface treatment agent with the hydrophobic polymeric pad and form the region of the polishing surface outside the grooves including the hydrophobic character.

According to another embodiment, a method of manufacturing a semiconductor device includes polishing a wafer by pressing a surface of the wafer against a polishing surface of a chemical mechanical polishing (CMP) pad while rotating both the wafer and the CMP pad; and supplying a slurry on the polishing surface of the CMP pad. The polishing surface of the CMP pad includes a first region including a hydrophobic character and a second region including a hydrophilic character. In an embodiment, the wafer is pressed against the second region of the polishing surface while rotating both the wafer and the CMP pad. In an embodiment, the first region of the polishing surface surrounds the second region of the polishing surface. In an embodiment, the polishing surface further includes a third region including a hydrophilic character. In an embodiment, the third region of the polishing surface surrounds the first region of the polishing surface. In an embodiment, the second region of the polishing surface surrounds the first region of the polishing surface. In an embodiment, the polishing surface further includes a third region including a hydrophobic character, and the third region surrounds the second region of the polishing surface. In an embodiment, the polishing surface further includes a third region including a hydrophobic character. In an embodiment, the third region of the polishing surface surrounds the second region of the polishing surface.

According to another embodiment, method of manufacturing a semiconductor device includes polishing a wafer by pressing a surface of the wafer against a polishing surface of a chemical mechanical polishing (CMP) pad while rotating both the wafer and the CMP pad; and supplying a slurry on the polishing surface of the CMP pad. The CMP polishing pad includes a sub pad layer, and a top pad layer affixed over the sub pad layer and including the polishing surface disposed away from the sub pad layer, wherein the top pad layer includes a first section including a hydrophobic polymeric material and a second section including a hydrophilic polymeric material, and the first and second sections are exposed on the polishing surface. In an embodiment, the wafer is pressed against the second section on the polishing surface while rotating both the wafer and the CMP pad. In an embodiment, the first section surrounds the second section on the polishing surface. In an embodiment, the top pad layer further includes a third section including a hydrophilic polymeric material, and the third section is exposed on the polishing surface. In an embodiment, the third section surrounds the first section on the polishing surface. In an embodiment, the second section surrounds the first section on the polishing surface. In an embodiment, the top pad layer further includes a third section including a hydrophobic polymeric material, and the third section is exposed on the polishing surface. In an embodiment, the third region surrounds the second region on the polishing surface.

According to another embodiment, a method of manufacturing a semiconductor device includes polishing a wafer by pressing a surface of the wafer against a polishing surface of a chemical mechanical polishing (CMP) pad while rotating both the wafer and the CMP pad; and supplying a slurry on the polishing surface of the CMP pad. The polishing surface includes a plurality of grooves formed therein, the grooves are lined with a material including a hydrophobic character, and a region of the polishing surface outside the grooves has a hydrophilic character. In an embodiment, the rotating CMP pad causes the slurry and the material removed from the wafer to flow through the grooves by centrifugal force. In an embodiment, the grooves intersect on the polishing surface and extend radially to a peripheral edge of the CMP pad. In an embodiment, the material including the hydrophobic character extends to portions of the polishing surface outside the grooves and is bounded by the region of the polishing surface outside the grooves including the hydrophilic character.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chemical mechanical polishing (CMP) pad comprising:
a polishing surface including a first region including a hydrophobic character and a second region including a hydrophilic character.

2. The CMP pad of claim 1, wherein the first region surrounds the second region.

3. The CMP pad of claim 2, wherein the polishing surface further includes a third region including a hydrophilic character.

4. The CMP pad of claim 3, wherein the third region surrounds the first region.

5. The CMP pad of claim 1, wherein the second region surrounds the first region.

6. The CMP pad of claim 5, wherein the polishing surface further includes a third region including a hydrophobic character.

7. The CMP pad of claim 6, wherein the third region surrounds the second region.

8. The CMP pad of claim 1, wherein the polishing surface comprises a hydrophobic polymeric material, and the second region of the polishing surface includes a surface treated area including the hydrophilic character.

9. The CMP pad of claim 1, further comprising a top pad layer forming the polishing surface, wherein the top pad layer includes a first section including a hydrophobic polymeric material forming the first region and a second section including a hydrophilic polymeric material forming the second region.

10. The CMP pad of claim 1, further comprising a plurality of grooves formed in the polishing surface.

11. The CMP pad of claim 10, wherein the first region lines the grooves, and the second region is disposed outside the grooves.

12. A method of manufacturing a chemical mechanical polishing (CMP) pad, the method comprising:
forming a polishing surface of the CMP pad to include a first region including a hydrophobic character and a second region including a hydrophilic character.

13. The method of claim 12, wherein the forming the polishing surface comprises:
forming a first section of pad including the hydrophobic character;
forming a second section of pad including the hydrophilic character;
combining the first and second sections to form a top pad layer including the polishing surface; and
affixing the top pad layer over a sub pad layer.

14. The method of claim 13, wherein the second section surrounds the first section on the polishing surface.

15. The method of claim 14, wherein the forming the polishing surface further comprises:
forming a third section of pad including a hydrophobic character; and
combining the third section of pad with the first and second sections of pad so that the third section surrounds the second section of pad on the polishing surface.

16. The method of claim 15, wherein the third section surrounds the second section of the pad on the polishing surface.

17. The method of claim 12, wherein the forming the polishing surface comprises providing a hydrophobic polymeric pad, surface treating a part of the hydrophobic polymeric pad with a surface treatment agent to form the second region of the polishing surface including the hydrophilic character, wherein a portion of the hydrophobic polymeric pad not treated with the surface treatment agent forms the first region of the polishing surface including the hydrophobic character.

18. A method of manufacturing a semiconductor device, the method comprising:
polishing a wafer by pressing a surface of the wafer against a polishing surface of a chemical mechanical polishing (CMP) pad while rotating both the wafer and the CMP pad; and
supplying a slurry on the polishing surface (106) of the CMP pad,
wherein the polishing surface of the CMP pad includes a first region including a hydrophobic character and a second region including a hydrophilic character.

19. The method of claim 18, wherein the second region of the polishing surface surrounds the first region of the polishing surface.

20. The method of claim 19, wherein the polishing surface further includes a third region including a hydrophobic character, and the third region surrounds the second region of the polishing surface.
